(19) United States
(12) Patent Application Publication
(10) Pub. No.: US 2025/0174057 A1
(43) Pub. Date: May 29, 2025

(54) BATTERY DIAGNOSTIC DEVICE, METHOD, AND NON-TRANSITORY STORAGE MEDIUM

(71) Applicant: TOYOTA JIDOSHA KABUSHIKI KAISHA, Toyota-shi (JP)

(72) Inventor: Naoki TSUDA, Toyota-shi (JP)

(73) Assignee: TOYOTA JIDOSHA KABUSHIKI KAISHA, Toyota-shi (JP)

(21) Appl. No.: 18/925,632

(22) Filed: Oct. 24, 2024

(30) Foreign Application Priority Data
Nov. 24, 2023 (JP) 2023-198820

(51) Int. Cl. G07C 5/08; G01R 31/00; G01R 31/392; H01M 10/42

(52) U.S. Cl. CPC G07C 5/0808; G01R 31/006; G01R 31/392; G07C 5/085; H01M 10/4285

(57) ABSTRACT

A battery diagnostic device configured to diagnose a state of a battery mounted on a vehicle includes a processor and a memory. The processor is configured to perform diagnostic discharge from the battery to a predetermined in-vehicle device at a second timing, the second timing being a timing when a predetermined time has elapsed from a first timing; acquire, during the diagnostic discharge, a physical quantity indicating the state of the battery; determine based on the physical quantity whether degradation diagnosis of the battery is possible; record the predetermined time as a successful discharge time from a plurality of successful discharge times when determination is made that the degradation diagnosis of the battery is possible; and perform the degradation diagnosis of the battery based on the physical quantity when determination is made that the degradation diagnosis of the battery is possible.

### CROSS-REFERENCE TO RELATED APPLICATION

This application claims priority to Japanese Patent Application No. 2023-198820 filed on Nov. 24, 2023, incorporated herein by reference in its entirety.

### BACKGROUND

### 1. Technical Field

The present disclosure relates to battery diagnostic devices, methods, and non-transitory storage mediums for diagnosing the state of a battery mounted on a vehicle.

### 2. Description of Related Art

Japanese Unexamined Patent Application Publication No. 2022-064649 (JP 2022-064649 A) discloses a battery diagnostic method for performing degradation diagnosis of a sub-battery that can back up a main battery during autonomous driving. In this battery diagnostic method, when degradation diagnosis of the sub-battery cannot be performed by the first diagnostic discharge process, the diagnostic discharge process is repeated a plurality of times to increase opportunities of degradation diagnosis of the sub-battery.

### SUMMARY

Even when a plurality of opportunities of degradation diagnosis of a battery is provided as in the battery diagnostic method described in JP 2022-064649 A, the battery may need to be charged and discharged many times before the diagnostic discharge process is successfully performed, or all the diagnostic discharge processes may fail, if the timing of diagnostic discharge often overlaps the timing of a current demand from an in-vehicle device. If all the diagnostic discharge processes fail and degradation diagnosis of the battery cannot be performed, the diagnosis accuracy decreases.

The present disclosure provides a battery diagnostic device etc. that can increase the probability that a diagnostic discharge process will be successfully performed and can thus improve the accuracy of battery diagnosis.

An aspect of the technique of the present disclosure is a battery diagnostic device configured to diagnose a state of a battery mounted on a vehicle. The battery diagnostic device includes a processor and a memory. The processor is configured to perform diagnostic discharge from the battery to a predetermined in-vehicle device at a second timing, the second timing being a timing when a predetermined time has elapsed from a first timing; acquire, during the diagnostic discharge, a physical quantity indicating the state of the battery; determine based on the physical quantity whether degradation diagnosis of the battery is possible; record the predetermined time as a successful discharge time when determination is made that the degradation diagnosis of the battery is possible; and perform the degradation diagnosis of the battery based on the physical quantity when determination is made that the degradation diagnosis of the battery is possible.

According to the battery diagnostic device etc. of the present disclosure, the timing to perform the diagnostic discharge process is determined based on the past successful discharge time. Accordingly, the diagnostic discharge process can be successfully performed with high probability, which improves the battery diagnosis accuracy.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a functional block diagram of a battery diagnostic device according to an embodiment and its peripheral components;

FIG. 2 shows current discharge paths from a second battery in a diagnostic discharge process;

FIG. 3 shows an example of changes in physical quantities of the second battery during the diagnostic discharge process;

FIG. 4 shows an example of successful discharge times recorded by a recording unit;

FIG. 5 shows an example of unsuccessful discharge times recorded by the recording unit;

FIG. 6A is a flowchart of a battery diagnostic process that is performed by the battery diagnostic device; and

FIG. 6B is a flowchart of the battery diagnostic process that is performed by the battery diagnostic device.

### DETAILED DESCRIPTION OF EMBODIMENTS

The present disclosure provides a battery diagnostic device that performs degradation diagnosis of a sub-battery that can back up a main battery during autonomous driving. This battery diagnostic device records each timing when a diagnostic discharge process was successfully performed (or failed) in the past, and performs future diagnostic discharge processes based on the recorded timings. Therefore, a battery diagnostic process can be performed at such a timing that the diagnostic discharge process will be successful with high probability, which improves the battery diagnosis accuracy.

Hereinafter, an embodiment of the present disclosure will be described in detail with reference to the drawings.

### Embodiment

### Configuration

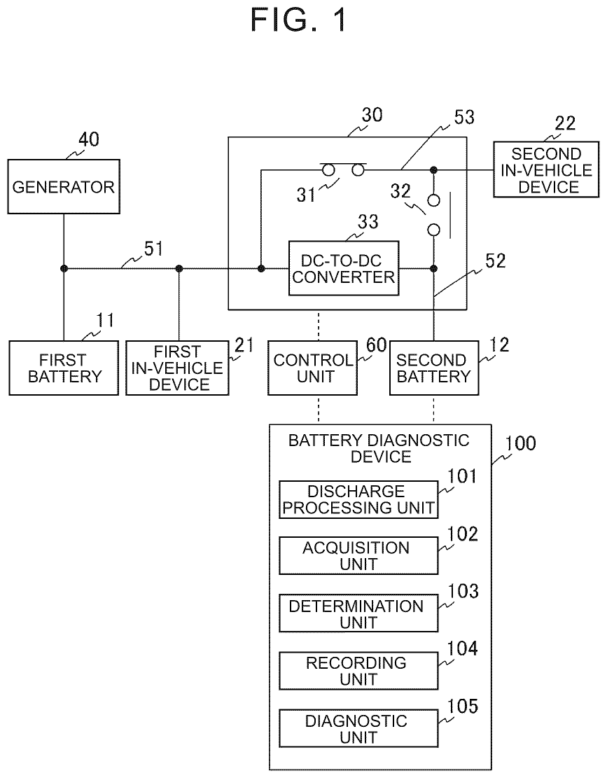

FIG. 1 is a functional block diagram of a battery diagnostic device 100 according to an embodiment of the present disclosure and its peripheral components. The functional blocks illustrated in FIG. 1 include a first battery 11, a second battery 12, a first in-vehicle device 21, a second in-vehicle device 22, a connection switching unit 30, a generator 40, a control unit 60, and the battery diagnostic device 100.

The first battery 11, the first in-vehicle device 21, the connection switching unit 30, and the generator 40 are connected to each other by a first power line 51. The second battery 12 and the connection switching unit 30 are connected by a second power line 52. The second in-vehicle device 22 and the connection switching unit 30 are connected by a third power line 53. The second battery 12, the connection switching unit 30, the control unit 60, and the battery diagnostic device 100 are connected by signal lines (dashed lines in FIG. 1), and send and receive control signals, measured values, etc.

An example will be described below in which the battery diagnostic device 100 according to the present embodiment is mounted on a vehicle switchable between manual driving and autonomous driving and including a power supply system that requires a redundant power supply configuration.

The generator 40 is a device that can output predetermined electric power, such as an alternator or a direct current-to-direct current (DC-to-DC) converter. The electric power output from the generator 40 is supplied to the first battery 11, the first in-vehicle device 21, etc.

The first battery 11 is a rechargeable secondary battery such as, for example, a lead-acid battery or a lithium-ion battery. The first battery 11 stores the electric power output from the generator 40, and releases the stored electric power to the first in-vehicle device 21 and the connection switching unit 30. The first battery 11 is provided as a main battery that is used exclusively for traction of the vehicle.

The second battery 12 is a rechargeable secondary battery such as, for example, a lead-acid battery or a lithium-ion battery. The second battery 12 stores the electric power output from the generator 40 and the electric power of the first battery 11 via the connection switching unit 30, and releases (supplies) the stored electric power to the second in-vehicle device 22 etc. via the connection switching unit 30. The second battery 12 is provided redundantly so that, even when the first battery 11 fails during autonomous driving, the second battery 12 can perform a backup process of maintaining power supply to the second in-vehicle device 22 responsible for autonomous driving in place of the first battery 11.

The first in-vehicle device 21 is a load that is installed in the vehicle and that consumes electric power. The first in-vehicle device 21 is configured to run on the electric power output from the generator 40 and/or the electric power stored in the first battery 11.

The second in-vehicle device 22 is a load that is installed in the vehicle and that consumes electric power, and can be a device that requires more stable electric power supply than the first in-vehicle device 21 during autonomous driving of the vehicle. More specifically, the second in-vehicle device 22 is an important device related to safe driving of the vehicle that requires power supply at a predetermined current for a predetermined time from the second battery 12 even if the power supply from the first battery 11 fails. For example, the second in-vehicle device 22 can be a device that performs an important function to cause the vehicle to safely perform a retreat action in case an emergency occurs during autonomous driving. The second in-vehicle device 22 is configured to run on the electric power output from the generator 40 and/or the electric power stored in the first battery 11 during manual driving, and is configured to run on the electric power output from the generator 40 whose voltage is controlled by a DC-to-DC converter 33 and/or the electric power stored in the first battery 11, and the electric power stored in the second battery 12 during autonomous driving.

The connection switching unit 30 includes a first switch 31, a second switch 32, and the DC-to-DC converter 33. The first switch 31 that can be opened and closed is disposed between the first power line 51 and the third power line 53. The second switch 32 that can be opened and closed is disposed between the second power line 52 and the third power line 53. The first switch 31 and the second switch 32 may be, for example, a semiconductor relay or a mechanical relay. The DC-to-DC converter 33 is a voltage converter that is disposed between the first power line 51 and the second power line 52 and that converts the voltage of the input electric power to a predetermined voltage and outputs the predetermined voltage. The DC-to-DC converter 33 may be, for example, a buck-boost DC-to-DC converter that has both a step-down function to step down the voltage on a primary side and output the resultant voltage to a secondary side and a step-up function to step up the voltage on the secondary side and output the resultant voltage to the primary side.

The control unit 60 is, for example, an autonomous driving electronic control unit (ECU) including a microcomputer. The control unit 60 controls the open/closed states of the first and second switches 31, 32 of the connection switching unit 30 and the voltage instruction value of the DC-to-DC converter 33, based on vehicle information (ignition ON/OFF state, manual driving/autonomous driving state, etc.) acquired from an in-vehicle device, not shown.

Specifically, when the vehicle is in the manual driving state, the control unit 60 closes the first switch 31 to connect the first power line 51 and the third power line 53, and opens the second switch 32 to disconnect the second power line 52 and the third power line 53. As a result, the electric power output from the generator 40 and/or the electric power stored in the first battery 11 are directly supplied to the second in-vehicle device 22. On the other hand, when the vehicle is in the autonomous driving state, the control unit 60 opens the first switch 31 to disconnect the first power line 51 and the third power line 53, and closes the second switch 32 to connect the second power line 52 and the third power line 53. As a result, the electric power output from the generator 40 and/or the electric power stored in the first battery 11 are indirectly supplied to the second in-vehicle device 22 via the DC-to-DC converter 33.

The battery diagnostic device 100 is a device for diagnosing the state of the second battery 12. More specifically, the battery diagnostic device 100 can perform diagnosis regarding degradation of the second battery 12. The battery diagnostic device 100 includes a discharge processing unit 101, an acquisition unit 102, a determination unit 103, a recording unit 104, and a diagnostic unit 105.

When the timing to perform degradation diagnosis of the second battery 12 comes, the discharge processing unit 101 performs a diagnostic discharge process of discharging from the second battery 12 to the first in-vehicle device 21 and the second in-vehicle device 22 for a first time period. The timing to perform degradation diagnosis of the second battery 12 is determined based on a successful discharge time or unsuccessful discharge time recorded by the recording unit 104, which will be described later, and is updated as necessary.

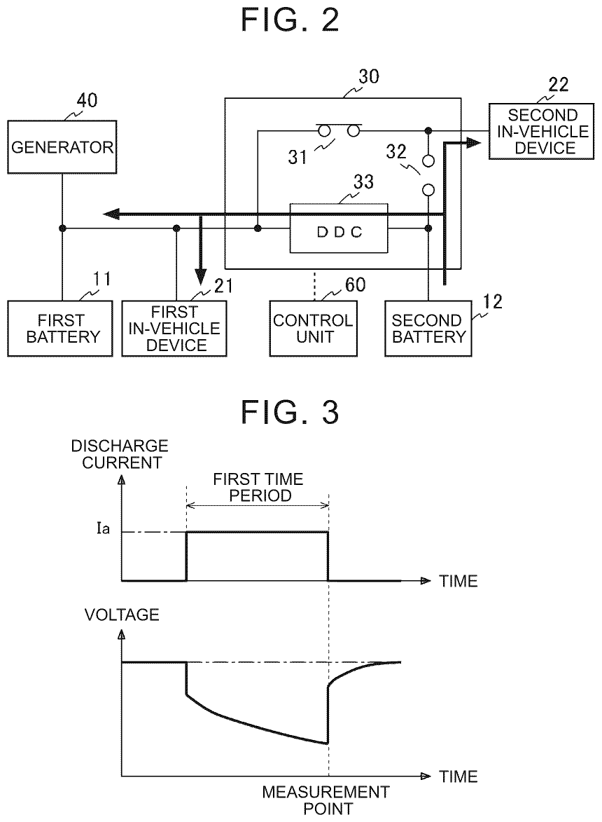

FIG. 2 shows current discharge paths (arrows in FIG. 2) in the diagnostic discharge process performed by the discharge processing unit 101. A current is discharged to the first in-vehicle device 21 via the DC-to-DC converter (DDC) 33, and is discharged to the second in-vehicle device 22 via the second switch 32. FIG. 3 also shows changes in discharge current and output voltage of the second battery 12 during diagnostic discharge. As shown in FIG. 3, the DC-to-DC converter (DDC) 33 controls so that a current having a constant value Ia continuously discharged from the second battery 12 for the first time period during the diagnostic discharge. The constant value Ia is appropriately set based on the current (actual backup current) that needs to be continuously supplied from the second battery 12 to the second in-vehicle device 22 for the first time period (e.g., 15 seconds) during the backup process. This diagnostic discharge process may be repeated one or two more times depending on the determination result from the determination unit 103 described later.

The acquisition unit 102 acquires physical quantities indicating the state of the second battery 12 while the discharge processing unit 101 is performing the diagnostic discharge process. The physical quantities indicating the state of the second battery 12 can be acquired from detection devices, not shown, such as sensors installed in the vehicle. Examples of the physical quantities indicating the state of the second battery 12 include voltage, current, and temperature. In the present embodiment, the acquisition unit 102 acquires the current (discharge current) discharged from the second battery 12 and the output voltage of the second battery 12 as the physical quantities. The acquisition unit 102 can also acquire the internal resistance and the state of charge (SOC) from the voltage, current, and temperature.

The determination unit 103 determines whether diagnosis regarding degradation of the second battery 12 is possible, based on the physical quantities indicating the state of the second battery 12 acquired by the acquisition unit 102. For example, degradation diagnosis of the second battery 12 is performed by determining whether the available electric power of the second battery 12 that is derived from the discharge current and output voltage of the second battery 12 obtained by the diagnostic discharge process satisfies the electric power required for a backup power supply for the first battery 11. Therefore, the discharge current and output voltage of the second battery 12 acquired by the acquisition unit 102 need to be accurate. The determination unit 103 determines whether degradation diagnosis of the second battery 12 is possible, based on whether the discharge current and output voltage of the second battery 12 acquired by the acquisition unit 102 are accurate. The accuracy of the discharge current and output voltage of the second battery 12 will be described later.

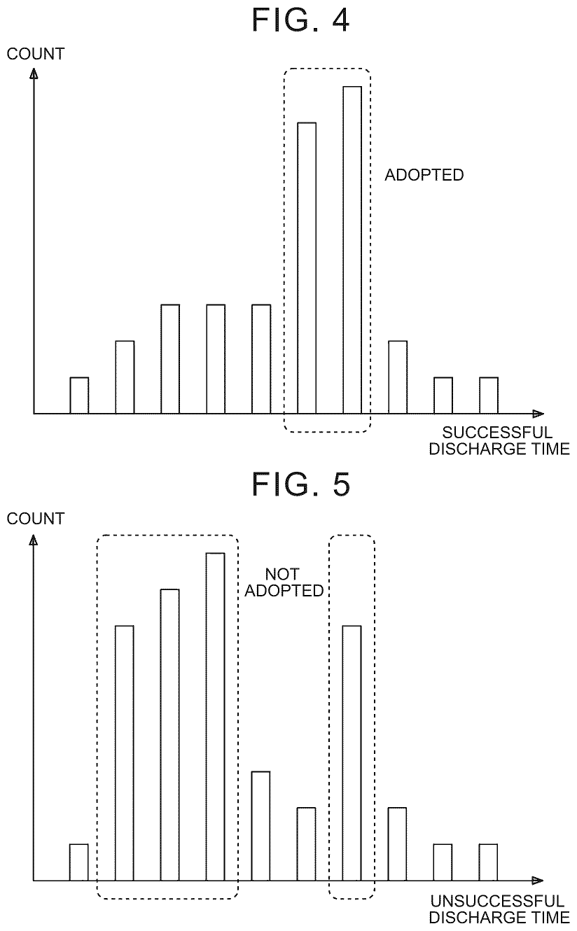

When the determination unit 103 determines that diagnosis regarding degradation of the second battery 12 is possible, the recording unit 104 records the time from a predetermined reference timing (first timing) to a timing to perform degradation diagnosis of the second battery 12 (second timing) as a successful discharge time. FIG. 4 shows an example of successful discharge times recorded by the recording unit 104. In the example of FIG. 4, the number of successful discharge times is cumulatively recorded for each time period determined as desired. In this case, the timing to perform degradation diagnosis of the second battery 12 by the discharge processing unit 101 is determined based on the successful discharge times (adopted) surrounded by a dashed line in FIG. 4.

When the determination unit 103 determines that diagnosis regarding degradation of the second battery 12 is not possible, the recording unit 104 may record the time from the predetermined reference timing (first timing) to the timing to perform degradation diagnosis of the second battery 12 (second timing) as an unsuccessful discharge time. FIG. 5 shows an example of unsuccessful discharge times recorded by the recording unit 104. In the example of FIG. 5, the number of unsuccessful discharge times is cumulatively recorded for each time period determined as desired. In this case, the timing to perform degradation diagnosis of the second battery 12 by the discharge processing unit 101 is determined based on the times other than the unsuccessful discharge times (not adopted) surrounded by a dashed line in FIG. 5.

For example, the successful discharge times and unsuccessful discharge times recorded by the recording unit 104 are reset when the second battery 12 or an electronic control unit (ECU) that consumes a current is replaced.

When the determination unit 103 determines that diagnosis regarding degradation of the second battery 12 is possible, the diagnostic unit 105 performs degradation diagnosis of the second battery 12 based on the physical quantities indicating the state of the second battery 12 (discharge current and output voltage) acquired by the acquisition unit 102. In this degradation diagnosis, it is diagnosed whether the second battery 12 is available to back up the first battery 11 in case the first battery 11 fails.

Part or whole of the battery diagnostic device 100 described above may be typically configured as an electronic control unit (ECU) that includes a processor such as a microcomputer, a memory, and an input and output interface. This electronic control unit can implement part or all of the functions of the discharge processing unit 101, acquisition unit 102, determination unit 103, recording unit 104, and diagnostic unit 105 by the processor reading and executing programs stored in the memory.

### Control

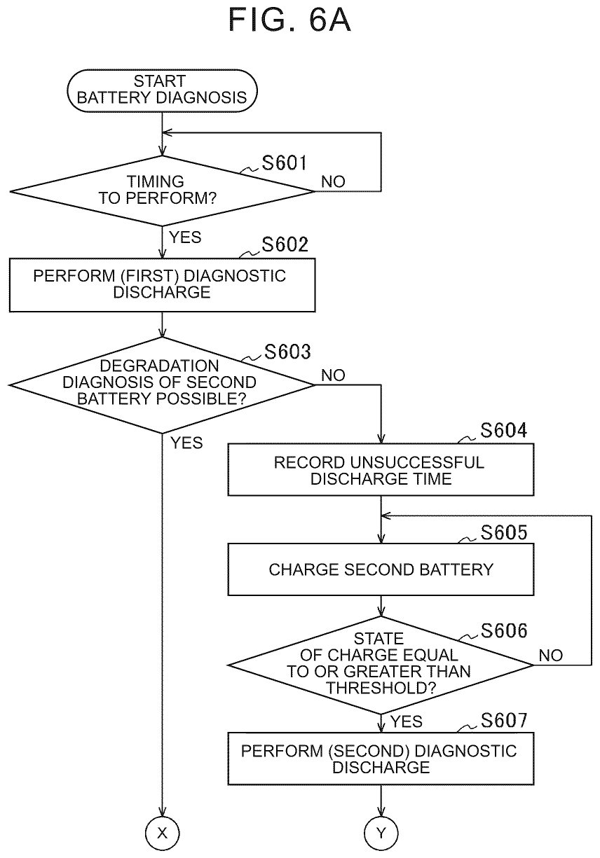

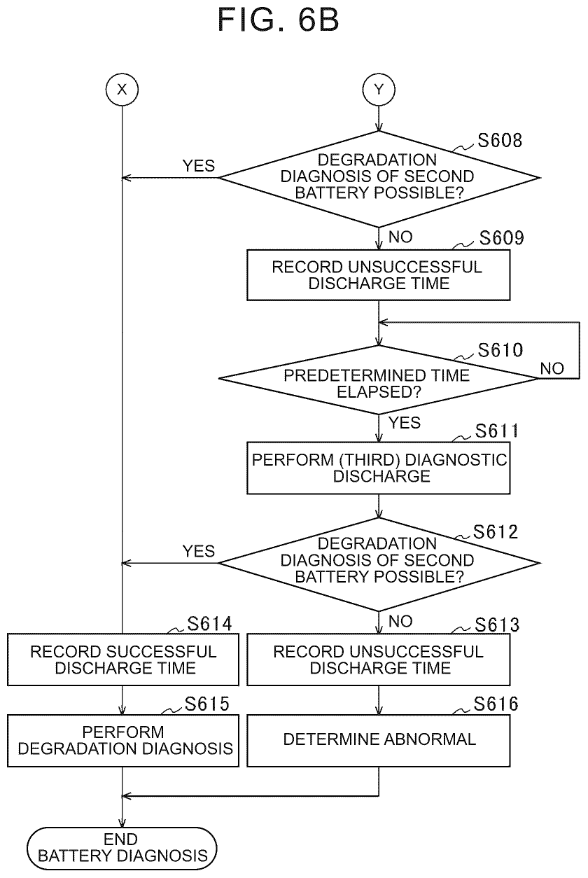

Next, control that is performed by the battery diagnostic device 100 according to the present embodiment will be described with further reference to FIGS. 6A and 6B. FIGS. 6A and 6B are flowcharts illustrating the procedure of a diagnostic process regarding degradation of the second battery 12 (battery diagnostic process) that is performed by the components of the battery diagnostic device 100 during manual driving. The process of FIG. 6A and the process of FIG. 6B are connected by connectors X, Y.

The battery diagnostic process illustrated in FIGS. 6A and 6B is started when the ignition of the vehicle is turned on (IG-ON). This battery diagnostic process ends when the vehicle is switched from manual driving to autonomous driving.

### Step S601

The discharge processing unit 101 determines whether the timing to perform the diagnostic discharge process (second timing) has come. For example, the second timing can be determined by any of the following methods by using the time point when the ignition of the vehicle is turned on (IG-ON) as the reference timing (first timing). The reference timing is not limited to when IG-ON, and may be any timing that serves as an absolute reference.

A first method is a method in which the time point when the successful discharge time recorded the largest number of times out of the successful discharge times recorded by the recording unit 104 has elapsed from the first timing is determined to be the second timing. Determining the second timing based on the time corresponding to the many past successful diagnostic discharge processes as in the first method can increase the probability that the current diagnostic discharge process will be successful.

A second method is a method in which the time point when the average time of the successful discharge times recorded by the recording unit 104 has elapsed from the first timing is determined to be the second timing. Determining the second timing based on the average value of the times corresponding to the past successful diagnostic discharge processes as in the second method can increase the probability that the current diagnostic discharge process will be successful.

A third method is a method in which the time point when any time other than the unsuccessful discharge times recorded by the recording unit 104 has elapsed from the first timing is determined to be the second timing. Determining the second timing based on the times other than the times corresponding to the past unsuccessful diagnostic discharge processes as in the third method can reduce the probability that the current diagnostic discharge process will fail and can increase the probability that the current diagnostic discharge process will be successful.

The process waits until the timing to perform the diagnostic discharge process (second timing) comes (NO in S601). When the timing (second timing) comes (YES in S601), the process proceeds to step S602.

### Step S602

The discharge processing unit 101 performs the first diagnostic discharge process. As described above, diagnostic discharge is performed by discharging a current having the constant value Ia from the second battery 12 to the first in-vehicle device 21 and the second in-vehicle device 22 (FIG. 2) for the first time period (FIG. 3). The acquisition unit 102 acquires the physical quantities of the second battery 12 as appropriate during this diagnostic discharge. Once the first diagnostic discharge process is performed, the process proceeds to step S603.

### Step S603

The determination unit 103 determines whether diagnosis regarding degradation of the second battery 12 is possible. For example, this determination is made by determining, based on the physical quantities of the second battery 12 acquired by the acquisition unit 102, whether the following conditions are satisfied.

(1) The average value of the discharge current of the second battery 12 during the first time period that is a discharge period is not equal to or greater than a first threshold.
(2) The discharge current of the second battery 12 at the end of discharge (measurement point in FIG. 3), that is, when the first time period has elapsed, is not equal to or greater than a second threshold.

The condition (1) is intended for a situation where a current demand from the second in-vehicle device 22 is too high to be absorbed by the control performed by the DC-to-DC converter 33. In such a situation, the current supplied from the second battery 12 to the second in-vehicle device 22 during the diagnostic discharge is disturbed. As a result, battery degradation cannot be correctly diagnosed using the physical quantities of the second battery 12 acquired by the acquisition unit 102. Whether the condition (1) is satisfied is therefore determined. The first threshold is appropriately set based on the current having the constant value Ia discharged during the diagnostic discharge and the actual backup current.

The condition (2) is intended for a situation where the condition (1) is satisfied but the discharge current of the second battery 12 changes significantly at the end of discharge, that is, when the first time period has elapsed. In such a situation, the available electric power of the second battery 12 (=discharge current×output voltage) derived from the physical quantities of the second battery 12 acquired by the acquisition unit 102 fluctuates. As a result, battery degradation cannot be correctly diagnosed. Whether the condition (2) is satisfied is therefore determined. The second threshold is appropriately set based on the electric power required to be supplied from the second battery 12 as a backup power supply for the first battery 11.

When either of the conditions (1), (2) is not satisfied, that is, when the average value of the discharge current of the second battery 12 during the first time period is equal to or greater than the first threshold or when the discharge current of the second battery 12 at the end of discharge, namely when the first time period has elapsed, is equal to or greater than the second threshold, the determination unit 103 determines that battery degradation diagnosis is not possible.

When degradation diagnosis of the second battery 12 is possible (YES in S603), the process proceeds to step S614. When degradation diagnosis of the second battery 12 is not possible (NO in S603), the process proceeds to step S604.

### Step S604

The recording unit 104 records the time from the first timing (when IG-ON) to the start of the first diagnostic discharge process (in this case, the second timing) as an unsuccessful discharge time. Once the unsuccessful discharge time is recorded, the process proceeds to step S605.

### Step S605

The discharge processing unit 101 charges the second battery 12 in preparation for the second diagnostic discharge process. This charging is performed by the discharge processing unit 101 instructing the control unit 60 to control the DC-to-DC converter 33. Once the second battery 12 is charged, the process proceeds to step S606.

### Step S606

The discharge processing unit 101 determines whether the state of charge of the second battery 12 has reached a predetermined value (first state of charge). This determination is made in preparation for the case where the third diagnostic discharge process is performed after the second diagnostic discharge process. That is, the state of charge of the second battery 12 is increased in advance so that the state of charge of the second battery 12 will not decrease excessively even when diagnostic discharge is performed twice in a row. The charging is continued until the state of charge of the second battery 12 reaches the first state of charge (NO in S606). Once the state of charge of the second battery 12 reaches the first state of charge (YES in S606), the process proceeds to step S607.

### Step S607

The discharge processing unit 101 performs the second diagnostic discharge process (discharge process for re-diagnosis). The diagnostic discharge is performed as described above. In order to stabilize the discharge current of the second battery 12, it is desirable to perform the second diagnostic discharge process in a period during which there is no such high current demand from the second in-vehicle device 22 as that occurred during the first diagnostic discharge process. The timing to perform the second diagnostic discharge process may be determined based on the successful discharge times or unsuccessful discharge times recorded by the recording unit 104. The acquisition unit 102 acquires the physical quantities of the second battery 12 as appropriate during this diagnostic discharge. Once the second diagnostic discharge process is performed, the process proceeds to step S608.

### Step S608

The determination unit 103 determines whether diagnosis regarding degradation of the second battery 12 is possible. This determination is made as described above. When degradation diagnosis of the second battery 12 is possible (YES in S608), the process proceeds to step S614. When degradation diagnosis of the second battery 12 is not possible (NO in S608), the process proceeds to step S609.

### Step S609

The recording unit 104 records the time from the first timing (when IG-ON) to the start of the second diagnostic discharge process as an unsuccessful discharge time. Once the unsuccessful discharge time is recorded, the process proceeds to step S610.

### Step S610

The discharge processing unit 101 determines whether a predetermined time (second time period) has elapsed since the end of the second diagnostic discharge process. This determination is made in preparation for the third diagnostic discharge process. In other words, since polarization may have occurred in the second battery 12 immediately after the second battery 12 was discharged at a constant current (CC discharge) by the second diagnostic discharge process, this determination is made in order to eliminate the influence of the polarization. Therefore, the predetermined time (second time period) is set to be long enough to eliminate the polarization of the second battery 12. The time continues to be measured until the predetermined time elapses (NO in S610). Once the predetermined time has elapsed (YES in S610), the process proceeds to step S611.

### Step S611

The discharge processing unit 101 performs the third diagnostic discharge process (discharge process for re-diagnosis). The diagnostic discharge is performed as described above. The reason for performing the third diagnostic discharge process after the second diagnostic discharge process is that there is a high possibility that a high current demand from the second in-vehicle device 22 may not occur during the third diagnostic discharge process even if such a high current demand from the second in-vehicle device 22 occurred during the second diagnostic discharge process. The acquisition unit 102 acquires the physical quantities of the second battery 12 as appropriate during this diagnostic discharge. Once the third diagnostic discharge process is performed, the process proceeds to step S612.

### Step S612

The determination unit 103 determines whether diagnosis regarding degradation of the second battery 12 is possible. This determination is made as described above. When degradation diagnosis of the second battery 12 is possible (YES in S612), the process proceeds to step S614. When degradation diagnosis of the second battery 12 is not possible (NO in S612), the process proceeds to step S613.

### Step S613

The recording unit 104 records the time from the first timing (when IG-ON) to the start of the third diagnostic discharge process as an unsuccessful discharge time. Once the unsuccessful discharge time is recorded, the process proceeds to step S616.

### Step S614

The recording unit 104 records the time from the first timing (when IG-ON) to the start of the diagnostic discharge process as a successful discharge time. In this process, when it is determined in the first diagnostic discharge process that degradation diagnosis of the second battery 12 is possible (YES in S603), the time from the first timing to the start of the first diagnostic discharge process (second timing) is recorded as a successful discharge time. When it is determined in the second diagnostic discharge process that degradation diagnosis of the second battery 12 is possible (YES in S608), the time from the first timing to the start of the second diagnostic discharge process is recorded as a successful discharge time. When it is determined in the third diagnostic discharge process that degradation diagnosis of the second battery 12 is possible (YES in S612), the time from the first timing to the start of the third diagnostic discharge process is recorded as a successful discharge time. Once the successful discharge time is recorded, the process proceeds to step S615.

### Step S615

The diagnostic unit 105 performs diagnosis regarding degradation of the second battery 12. This degradation diagnosis is performed by determining, based on the physical quantities of the second battery 12 acquired by the acquisition unit 102, whether the available electric power of the second battery 12 is large enough to back up the first battery 11 in case the first battery 11 fails. More specifically, when it is determined in the first diagnostic discharge process that degradation diagnosis of the second battery 12 is possible (YES in S603), the physical quantities of the second battery 12 acquired by the acquisition unit 102 during the first diagnostic discharge are used for the diagnosis. When it is determined in the second diagnostic discharge process that degradation diagnosis of the second battery 12 is possible (YES in S608), the physical quantities of the second battery 12 acquired by the acquisition unit 102 during the second diagnostic discharge are used for the diagnosis. When it is determined in the third diagnostic discharge process that degradation diagnosis of the second battery 12 is possible (YES in S612), the physical quantities of the second battery 12 acquired by the acquisition unit 102 during the third diagnostic discharge are used for the diagnosis. This battery diagnosis process ends once the degradation state of the second battery 12 is diagnosed.

### Step S616

Since it is determined in the three diagnostic discharge processes that degradation diagnosis of the second battery 12 is not possible, the diagnostic unit 105 determines that the second battery 12 is in an abnormal state. This battery diagnostic process ends once it is determined that the second battery 12 is in an abnormal state.

### Functions and Effects

As described above, according to the battery diagnostic device 100 of one embodiment of the present disclosure, when the physical quantities that are accurate enough to allow degradation diagnosis of the second battery 12 cannot be acquired by the first diagnostic discharge process (first diagnostic discharge), the diagnostic discharge process (second or third diagnostic discharge) is repeated a plurality of times to acquire the physical quantities. This process increases the possibility that accurate physical quantities can be obtained, and thus increases opportunities of degradation diagnosis of the second battery 12.

According to the battery diagnostic device 100 of the embodiment, the timing to perform the first diagnostic discharge process (first diagnostic discharge) is determined based on the past successful or unsuccessful discharge times. Therefore, the battery diagnostic process can be performed at such a timing that the diagnostic discharge process will be successful with high probability, which improves the battery diagnosis accuracy.

Although one embodiment of the present disclosure is described above, the present disclosure can be interpreted as a battery diagnostic device, a method performed by a battery diagnostic device including a processor and a memory, a program for performing the method, a computer-readable non-transitory storage medium storing the program, and a vehicle equipped with a battery diagnostic device.

The battery diagnostic device etc. of the present disclosure can be used to diagnose the state of a battery mounted on a vehicle.

What is claimed is:

1. A battery diagnostic device configured to diagnose a state of a battery mounted on a vehicle, the battery diagnostic device comprising:
a processor; and
a memory, wherein
the processor is configured to:
perform diagnostic discharge from the battery to a predetermined in-vehicle device at a second timing, the second timing being a timing when a predetermined time has elapsed from a first timing;
acquire, during the diagnostic discharge, a physical quantity indicating the state of the battery;
determine based on the physical quantity whether degradation diagnosis of the battery is possible;
record the predetermined time as a successful discharge time from a plurality of successful discharge times when determination is made that the degradation diagnosis of the battery is possible; and
perform the degradation diagnosis of the battery based on the physical quantity when determination is made that the degradation diagnosis of the battery is possible.

2. The battery diagnostic device according to claim 1, wherein the processor is configured to perform the diagnostic discharge at the second timing using a successful discharge time recorded a largest number of times by the memory as the predetermined time.

3. The battery diagnostic device according to claim 1, wherein the processor is configured to perform the diagnostic discharge at the second timing using an average value of the plurality of successful discharge times recorded by the memory as the predetermined time.

4. The battery diagnostic device according to claim 1, wherein the memory is configured to record the predetermined time as an unsuccessful discharge time when determination is made that the degradation diagnosis of the battery is not possible, and
the processor is configured to perform the diagnostic discharge at the second timing using a time other than the unsuccessful discharge time recorded by the memory as the predetermined time.

5. The battery diagnostic device according to claim 4, wherein the processor is configured to, when determination is made that the degradation diagnosis of the battery is not possible, perform discharge for re-diagnosis from the battery to the predetermined in-vehicle device at a third timing when the time other than the unsuccessful discharge time recorded by the memory has elapsed from the first timing.

6. The battery diagnostic device according to claim 1, wherein the first timing is a timing when an ignition of the vehicle is turned on.

7. A method performed by a computer of a battery diagnostic device configured to diagnose a state of a battery mounted on a vehicle, the method comprising:
performing diagnostic discharge from the battery to a predetermined in-vehicle device at a second timing, the second timing being a timing when a predetermined time has elapsed from a first timing;
acquiring, during the diagnostic discharge, a physical quantity indicating the state of the battery;
determining based on the physical quantity whether degradation diagnosis of the battery is possible;
recording the predetermined time as a successful discharge time from a plurality of successful discharge times when determination is made that the degradation diagnosis of the battery is possible; and
performing the degradation diagnosis of the battery based on the physical quantity when determination is made that the degradation diagnosis of the battery is possible.

8. A non-transitory storage medium storing instructions that are executable by one or more processors of a battery diagnostic device configured to diagnose a state of a battery mounted on a vehicle and that cause the one or more processors to perform functions comprising:
performing diagnostic discharge from the battery to a predetermined in-vehicle device at a second timing, the second timing being a timing when a predetermined time has elapsed from a first timing;
acquiring, during the diagnostic discharge, a physical quantity indicating the state of the battery;
determining based on the physical quantity whether degradation diagnosis of the battery is possible;
recording the predetermined time as a successful discharge time from a plurality of successful discharge times when determination is made that the degradation diagnosis of the battery is possible; and
performing the degradation diagnosis of the battery based on the physical quantity when determination is made that the degradation diagnosis of the battery is possible.
